(19) United States
(12) Patent Application Publication
(10) Pub. No.: US 2019/0233938 A1
(43) Pub. Date: Aug. 1, 2019

(54) FILM FORMATION APPARATUS

(71) Applicant: ULVAC, Inc., Chigasaki-shi (JP)

(72) Inventors: Junsuke MATSUZAKI, Chigasaki-shi (JP); Hirohisa Takahashi, Chigasaki-shi (JP); Yuu Mizushima, Chigasaki-shi (JP)

(73) Assignee: ULVAC, Inc., Chigasaki-shi (JP)

(21) Appl. No.: 16/380,416

(22) Filed: Apr. 10, 2019

Related U.S. Application Data
(63) Continuation of application No. PCT/JP2017/039940, filed on Nov. 6, 2017.

(30) Foreign Application Priority Data
Nov. 4, 2016 (JP) 2016-216343

(51) Int. Cl. C23C 14/56; B65G 49/00; C23C 14/34; C23C 14/50; H01J 37/34

(52) U.S. Cl. CPC C23C 14/562; B65G 49/00; C23C 14/34; H01J 37/34; C23C 14/564; C23C 14/568; C23C 14/50

(57) ABSTRACT

In a vacuum chamber, there are first and second film formation regions, and a conveyance path having a projected shape on a vertical plane. The conveyance path has a continuous ring shape and passes through the first and second film formation regions. A substrate-holder conveyance mechanism has plural driving portions in contact with driven portions on the substrate holder and is configured to convey the substrate holder along the conveyance path such that the substrate holder remains horizontal. The driving portions convey a preceding substrate holder and a following substrate holder adjacent to each other through the respective film formation regions such that an end portion of an upstream side of a substrate holder at a downstream side in the moving direction and an end portion of a downstream side of a substrate holder at an upstream side in the moving direction are close to each other.

### INCORPORATION BY REFERENCE

This application is a Continuation of PCT/JP2017/039940 filed Nov. 6, 2017, and is based on and claims benefit of priority from earlier Japanese Patent Application No. 2016-216343 filed on Nov. 4, 2016, the descriptions of which are incorporated herein by reference.

### TECHNICAL

This application generally relates to a film formation apparatus that performs pass-through film formation on both surfaces of a substrate held by a substrate holder in a vacuum environment.

### BACKGROUND

Conventionally, a film formation apparatus that mounts each of a plurality of substrates to be film-formed on a substrate holder, such as a tray, and performs pass-through film formation on each of the plurality of substrates to be film-formed has been known.

In such a film formation apparatus, a substrate, which is an object to be film-formed, is introduced (loaded) into a vacuum chamber, and is held by a substrate holder. The substrate on which film formation is completed is removed from the substrate holder, and the substrate is ejected (unloaded) to the outside of the vacuum chamber.

In a configuration of the conventional technology, a film formation surface of the substrate remains horizontal from a loaded position to an unloaded position, and each process is performed on the substrate while the substrate moves along a ring-shaped conveyance path configured in a horizontal plane.

As a result, in such a conventional technology, there is a problem that it is inevitable to increase a size and complexity of the film formation apparatus.

In addition, when a plurality of substrate holders holding each substrate are conveyed to perform passthrough film formation, it is preferable to increase efficiency of film formation as much as possible.

However, in an apparatus that performs the pass-through film formation as discussed above, there is a problem that it is difficult to efficiently perform the film formation.

In addition, in an apparatus that performs film formation on both surfaces of the substrate, the difficulty of efficiently performing the film formation increases.

### SUMMARY

The present invention has been made in consideration of the above-mentioned problems in the conventional art. An objective of the present embodiments is to provide a pass-through film formation apparatus capable of efficiently forming a film on both surfaces of a substrate using a plurality of substrate holders and having a small and simple configuration.

An embodiment made to achieve the above objective is a film formation apparatus comprising a vacuum chamber in which a single vacuum environment is formed, a first film formation region provided in the vacuum chamber to form a first film on a substrate held by a substrate holder, a second film formation region provided below or above the first film formation region in the vacuum chamber to form a second film on the substrate held by the substrate holder, and a substrate-holder conveyance mechanism to allow a plurality of substrate holders passing through the first film formation region and the second film formation region. The substrate-holder conveyance mechanism includes a conveyance path formed such that a projected shape thereof on a vertical plane is a ring shape. A driving portion is in contact with a driven portion provided on each of the plurality of substrate holders to press the driven portion while maintaining a horizontal state of the substrate holder, and to move of the substrate holder along the conveyance path. The conveyance mechanism includes a first conveyance portion disposed from one end of the first film formation region to the other end of the first film formation region to allow the substrate holder passing through the first film formation region by the driving portion. The conveyance mechanism also includes a second conveyance portion disposed from one end of the second film formation region to the other end of the second film formation region to allow the substrate holder passing through the second film formation region by the driving portion. The substrate-holder conveyance mechanism is provided with a turning conveyance portion to move the substrate holder from the first conveyance portion to the second conveyance portion while maintaining the horizontal state of the substrate holder. The conveyance mechanism is also provided with a driving portion turning portion to move the driving portion from the second conveyance portion to the first conveyance portion.

An embodiment of the film formation apparatus further includes shield portions having a protrusion shape provided on an end portion of a downstream side in a moving direction of the substrate holder and an end portion of an upstream side in the moving direction of the substrate holder, so as to shield a film forming material.

An embodiment includes the shield portion of the upstream side in the moving direction of the preceding substrate holder and the shield portion of the downstream side in the moving direction of the following substrate holder of the shield portions among the two substrate holders moving adjacent each other are formed having different heights from a bottom surface of the substrate holder such that the shield portion of the upstream side and the shield portion of the downstream side are disposed to overlap each other when the substrate holders are moved.

An embodiment includes the substrate-holder conveyance mechanism having a conveyance driving member applied across two driving wheels rotating around rotation axes. The driving portion including a second driving portion and a first driving portion, each provided on the conveyance driving member. The driven portion of each of the substrate holders includes an upstream side driven portion provided on an upstream side in a moving direction of the substrate holder, and a downstream driven portion provided on a downstream side in the moving direction of the substrate holder. The driving portion for initial movement is in contact with the downstream side driven portion and presses the downstream side driven portion to linearly move the substrate holder. The first driving portion is disposed behind the second driving portion in the moving direction and is positioned on a side surface of the driving wheel positioned on the upstream side in the moving direction of the substrate holder linearly moved by the second driving portion, which is in contact with and presses the upstream side driven portion during rotation so as to move the substrate holder at a speed higher than a moving speed of the second driving portion.

An embodiment includes the film formation apparatus. Wherein the substrate holder is configured such that a plurality of substrates to be film-formed are arranged along a direction orthogonal to the moving direction.

In an embodiment, in the vacuum chamber in Which a single vacuum environment is formed, the conveyance path is formed such that a shape thereof projected on a vertical plane is a continuous ring shape. A substrate-holder conveyance mechanism that conveys the plurality of substrate holders along the conveyance path such that the plurality of substrate holders remain horizontal is provided. Therefore, a small film formation apparatus is provided.

The substrate-holder conveyance mechanism has a plurality of driving portions in contact with the driven portions provided on the plurality of substrate holders. The plurality of driving portions press and move the substrate holder in the moving direction. Because the driving portions are configured to convey two substrate holders adjacent to each other toward the film formation regions such that an end portion of the upstream side in the moving direction of the substrate holder of the downstream side in the moving direction and an end portion of the downstream side in the moving direction of the substrate holder of the upstream side in the moving direction are close to each other, it is possible to dispose as many substrate holders as possible in the conveyance path without performing a complicated control. As a result, it is possible to provide the film formation apparatus having a simple configuration and which efficiently performs film formation.

Furthermore, because an interval between the plurality of substrate holders can be made narrower than that in the conventional technology, it is possible to efficiently use a film formation material without wasting the film formation material, and an amount of the film formation material passing between the substrate holders can be reduced. Therefore, it is possible to reduce an amount of the film formation material attached to the inside of the vacuum chamber, and to prevent contamination of the film formation material in the vacuum chamber.

It is possible to provide a pass-through film formation apparatus capable of efficiently forming films on both surfaces of the substrate and having a small and simple configuration.

It is possible to prevent contamination of the film formation material in the vacuum chamber by the shield portions.

It is possible to move the plurality of substrate holders such that the plurality of substrate holders automatically approach each other by appropriately setting a distance between the driving portions.

In addition, in a state where the first and second conveyance portions are conveyed at a uniform velocity and the substrate holder is ejected from a first rotation driving means side, the substrate holder can also be accelerated by a driving portion for acceleration of the conveyance driving member. As a result, the ejected substrate holder can be automatically spaced apart from the following substrate holder and smoothly ejected.

When the substrate holder passes through a first rotation driving means in the case where the substrate holder is introduced from the first rotation driving means side, or in the case where the substrate holder is ejected from the first rotation driving means side, it is possible to easily accelerate the substrate holder by the driving portion to accelerate the conveyance driving member.

In addition, in the case where the substrate holder is configured to arrange and hold the plurality of substrates to be film-formed in a direction orthogonal to the moving direction, it is possible to reduce a length of the substrate holder and a surplus space depending on the length of the substrate holder, as compared to a case where film formation is performed by conveying the substrate holder arranging and holding the plurality of substrates in the moving direction of the substrate as in the conventional technology. It is thus possible to further save a space of the film formation apparatus.

### BRIEF DESCRIPTION OF THE DRAWINGS

FIG. 1 is a schematic view showing an entire configuration of a film formation apparatus according to one embodiment.

FIG. 2 is a plan view showing a basic configuration of a substrate-holder conveyance mechanism in the present embodiment.

FIG. 3 is a front view showing a configuration of main portions of the substrate-holder conveyance mechanism.

FIGS. 4(a) to 4(c) are views showing a configuration of a substrate holder used in the present embodiment, whereby FIG. 4(a) is a plan view, FIG. 4(b) is a front view, and FIG. 4(c) is an enlarged view showing the vicinity of a shield portion,

FIGS. 5(a) and 5(b) are explanatory diagrams showing a relationship between dimensions of first and second driving portions, and a dimension of the substrate holder in the substrate-holder conveyance mechanism.

FIG. 6 is an explanatory diagram showing an operation of introducing a substrate into a vacuum chamber (part 1).

FIG. 7 is an explanatory diagram showing the operation of introducing a. substrate into a vacuum chamber (part 2).

FIG. 8 is an explanatory diagram showing the operation of introducing a substrate into a vacuum chamber (part 3).

FIGS. 9(a) and 9(b) are explanatory diagrams of an operation in which the substrate holder is transferred to the substrate-holder conveyance mechanism in the present embodiment (part 1).

FIGS. 10(a) and 10(b) are explanatory diagrams of the operation in which the substrate holder is transferred to the substrate-holder conveyance mechanism in the present embodiment (part 2).

FIGS. 11(a) and 11(b) are explanatory diagrams of the operation in which the substrate holder is transferred to the substrate-holder conveyance mechanism in the present embodiment (part 3).

FIGS. 12(a) and 12(b) are explanatory diagrams of the operation in which the substrate holder is transferred to the substrate-holder conveyance mechanism in the present embodiment (part 4).

FIGS. 13(a) and 13(b) are explanatory diagrams of an operation in which the substrate holder is transferred to a substrate carry-in and carry-out mechanism in the present embodiment (part 1).

FIGS. 14(a) and 14(b) are explanatory diagrams of the operation in which the substrate holder is transferred to a substrate carry-in and carry-out mechanism in the present embodiment (part 2).

FIGS. 15(a) and 15(b) are explanatory diagrams of the operation in which the substrate holder is transferred to a substrate carry-in and carry-out mechanism in the present embodiment (part 3).

FIG. 16 is an explanatory diagram showing an operation of ejecting the substrate from the vacuum chamber (part 1).

FIG. 17 is an explanatory diagram showing the operation f ejecting the substrate from the vacuum chamber (part 2).

FIG. 18 is an explanatory diagram showing .he operation of ejecting the substrate from the vacuum chamber (part 3).

### DETAILED DESCRIPTION OF EMBODIMENTS

Hereinafter, embodiments will be discussed in detail with reference to the drawings.

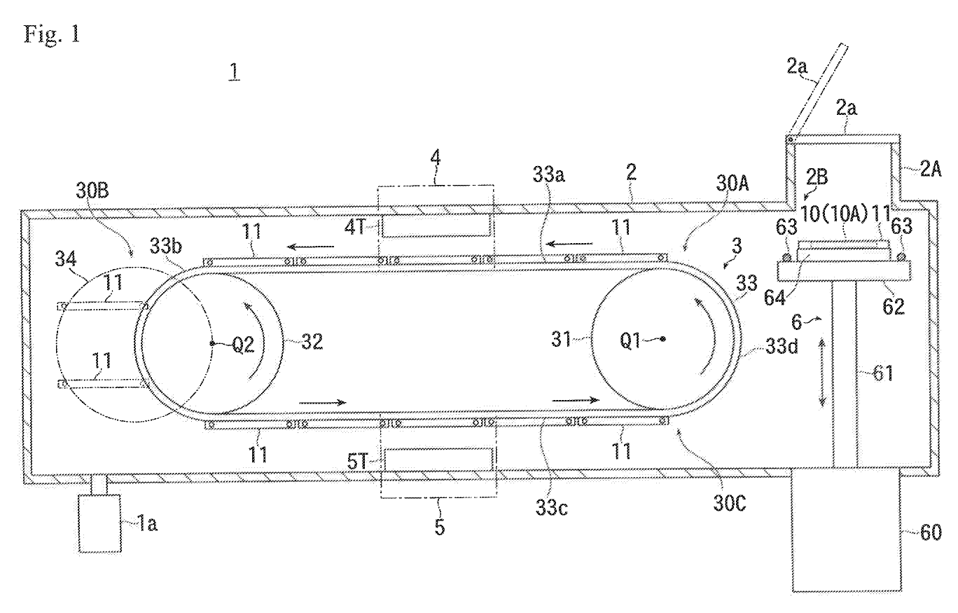

FIG. 1 is a schematic view showing an entire configuration of a film formation apparatus according to an embodiment.

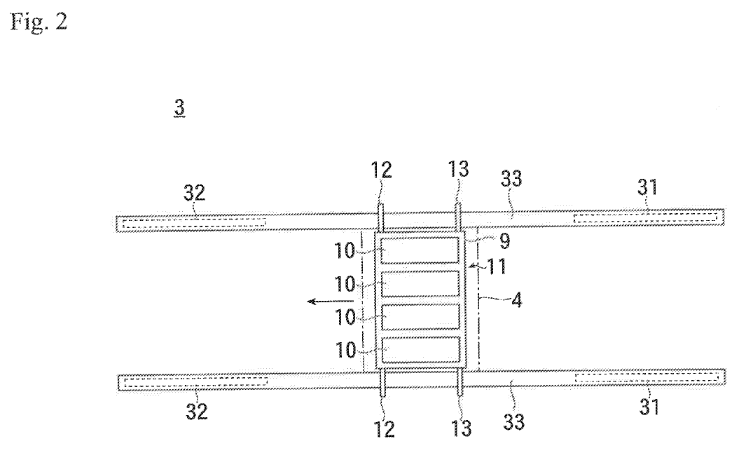

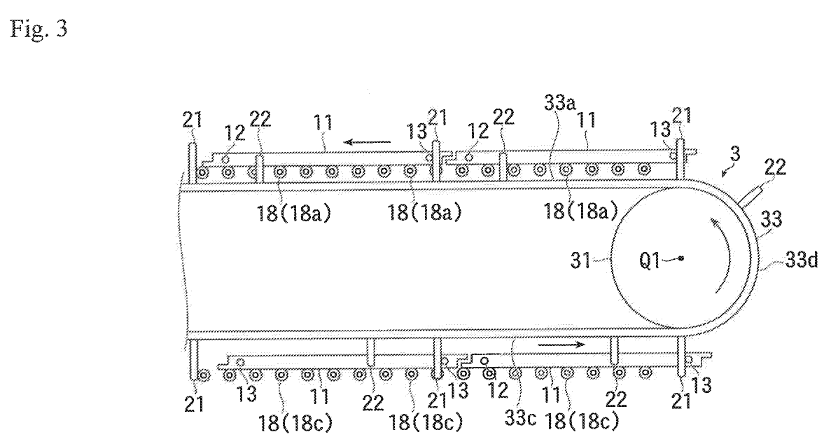

In addition, FIG. 2 is a plan view showing a basic configuration of a substrate-holder conveyance mechanism in the present embodiment, and FIG. 3 is a front view showing a configuration of main portions of the substrate-holder conveyance mechanism.

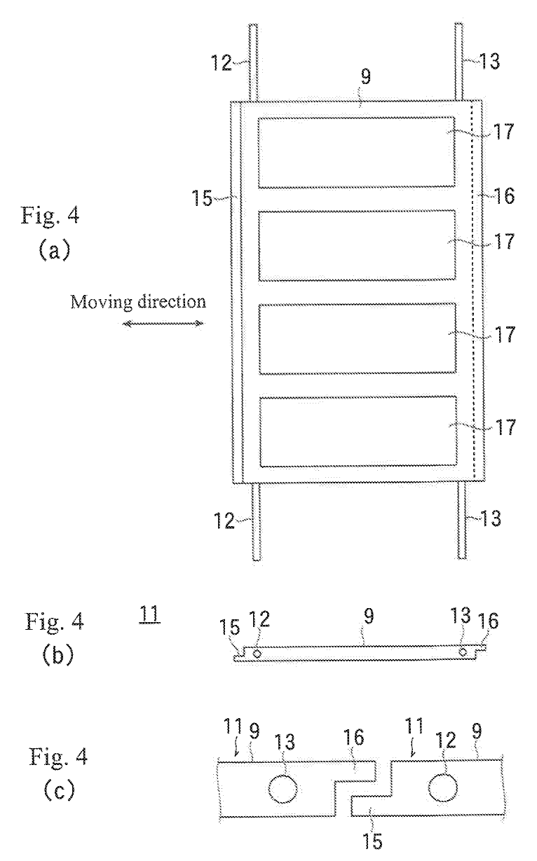

Further, FIGS. 4(a), 4(b) and 4(c) are views showing a configuration of a substrate holder used in the present embodiment, wherein FIG. 4(a) is a plan view, FIG. 4(b) is a front view, and FIG. 4(c) is an enlarged view showing the vicinity of a shield portion.

As shown in FIG. 1, a film formation apparatus 1 according to the present embodiment has a vacuum chamber 2, which is connected to a vacuum exhaust device la and in which a single vacuum environment is formed.

A substrate-holder conveyance mechanism 3 having a conveyance path to be discussed later and conveying substrate holders 11 along the conveyance path is provided in the vacuum chamber 2.

The substrate-holder conveyance mechanism 3 is configured to continuously convey a plurality of substrate holders 11 holding substrates 10 in a stale where the plurality of substrate holders 11 are close to each other.

Here, the substrate-holder conveyance mechanism 3 includes first and second driving wheels (first and second rotation driving means) 31 and 32 formed of, for example, a sprocket, operated by a rotational driving force transferred from a driving mechanism (not shown), and having a circular shape with the same diameter. The first and second driving wheels 31 and 32 are disposed with a predetermined distance therebetween in a state where the respective rotation axes Q1 and Q2 are made parallel with each other.

Two conveyance driving members 33 formed of, for example, chains, are spaced apart from each other and are hung across the first and second driving wheels 31 and 32.

Further, as shown in FIG. 2, structures in which the two conveyance driving members 33 are hung across the first and second driving wheels 31 and 32 are disposed in parallel with each other with a predetermined distance therebetween, such that a conveyance path having a ring shape with respect to a vertically disposed plane (this plane is a plane disposed perpendicular to a horizontal plane and is referred to as a vertical plane) is formed.

In the present embodiment, in a conveyance driving member of an upper side of the conveyance driving members 33 constituting the conveyance path, a forward path-side conveyance portion (also referred to as a first conveyance portion) 33a moving from the first driving wheel 31 toward the second driving wheel 32 to convey the substrate holder 11 in a first moving direction is formed. In addition, a turning portion 33b turning a moving direction of the substrate holder 11 by the conveyance driving member 33 of the surrounding portion of the second driving wheel 32 to convert the moving direction in an opposite direction is formed. Therefore, in a conveyance driving member of a lower side of the two conveyance driving members 33, a return path-side conveyance portion (also referred to as a second conveyance portion) 33c moving from the second driving wheel 32 toward the first driving wheel 31 to convey the substrate holder 11 in a second moving direction is formed.

The substrate-holder conveyance mechanism 3 according to the present embodiment is configured such that the forward path-side conveyance portion 33a positioned on the upper side of each conveyance driving member 33 and the return path-side conveyance portion 33c positioned on the lower side of each conveyance driving member 33 face each other, and overlap each other in a vertical direction (see FIGS. 1 and 2).

In addition, the substrate-holder conveyance mechanism 3 is provided with a substrate-holder introduction portion 30A introducing the substrate holder 11, a turning conveyance portion 30B turning and conveying the substrate holder 11, and a substrate-holder ejection portion 30C ejecting the substrate holder 11.

Here, the turning conveyance portion 30B has, for example, a reversing portion 34 formed in a continuous ring shape, each substrate holder 11 is supported by a plurality of supporters (not shown) provided in the reversing portion 34 and a plurality of supporters (not shown) provided in the turning portion 33b of the conveyance driving member 33, and a substrate holder 11 on which movement in a predetermined direction on the forward path-side conveyance portion 33a ends moves to the return path-side conveyance portion 33c to start a movement in a direction opposite to a direction in which the substrate holder 11 moves on the forward path-side conveyance portion 33a.

A surface of the substrate holder 11 that faces vertically upward when the substrate holder 11 moves on the forward path-side conveyance portion 33a is maintained in a state where the surface faces vertically upward both when the substrate holder 11 moves from the forward path-side conveyance portion 33a to the return path-side conveyance portion 33c and when the substrate holder 11 moves on the return path-side conveyance portion 33c.

In addition, in the present embodiment, the first and second driving wheels 31 and 32 are rotated at a predetermined speed in the same rotation direction about the rotation axes Q1 and Q2, respectively, so that side surfaces of both of the first and second driving wheels 31 and 32 move at the same speed by a rotation device, such as a motor.

Bach of the conveyance driving members 33 is in contact with the side surfaces of the first and second driving wheels 31 and 32, and a portion of the conveyance driving member 33 in contact with the first driving wheel 31 and a portion of the conveyance driving member 33 in contact with the second driving wheel 32 rotationally move together with the first and second driving wheels 31 and 32 without slipping, so as to rotationally move from a rear side in a moving direction to a front side in the moving direction. On the other hand, between the first driving wheel 31 and the second driving wheel 32, each conveyance driving member 33 linearly moves from the rear side in the moving direction (upstream side in the moving direction) to the front side in the moving direction (downstream side in the moving direction).

Each of the conveyance driving members 33 is formed of a material that does not expand and contract, and is spanned between the first and second driving wheels 31 and 32 so as not to slacken, and each of the conveyance driving members 33 is disposed in a horizontal planar shape in the forward path-side conveyance portion 33a and the return path-side conveyance portion 33e. Therefore, each of the conveyance driving members 33 between the first and second driving wheels 31 and 32 is configured to move at the same speed as a movement speed of the side surfaces of the first and second driving wheels 31 and 32.

In the present embodiment, in the vacuum chamber 2, a first film formation region 4, which is a space facing a sputtering source 4T disposed above the substrate-holder conveyance mechanism 3, is provided, and a second film formation region 5, which is a space facing a sputtering source 5T disposed under the substrate-holder conveyance mechanism 3, is provided.

It should be noted that gas introduction mechanisms (not shown) introducing a predetermined sputtering gas are provided in the first and second film formation regions 4 and 5, respectively.

In the present embodiment, the forward path-side conveyance portion 33a having the conveyance driving member 33 as discussed above is linearly disposed from one end of the first film formation region 4 to another end thereof, and the substrate holder 11 moving along a conveyance path in the forward path-side conveyance portion 33a is configured to move in a horizontal direction between one end and the other end of the first film formation region 4 so as to pass through the first film formation region 4 as discussed later.

Likewise, the return path-side conveyance portion 33c having the conveyance driving member 33 is linearly disposed from one end of the second film formation region 5 to the other end thereof, and the substrate holder 11 moving along a conveyance path in the return path-side conveyance portion 33c is configured to move in the horizontal direction between one end and the other end of the second film formation region 5 so as to pass through the second film formation region 5 as discussed later.

Then, when the substrate holder 11 passes through the forward path-side conveyance portion 33a and the return path-side conveyance portion 330 having the conveyance driving members 33 constituting the conveyance path, a plurality of substrates 10 (see FIG. 2) held by the substrate holder 11 move in a horizontal state.

A substrate carry-in and carry-out mechanism 6 for transferring the substrate holder 11 to the substrate-holder conveyance mechanism 3 and receiving the substrate holder 11 from the substrate-holder conveyance mechanism 3 is provided at a position of the vicinity of the substrate-holder conveyance mechanism 3 in the vacuum chamber 2, for example, at a position adjacent to the first driving wheels 31.

The substrate carry-in and carry-out mechanism 6 according to the present embodiment has a supporter 62 provided on a tip portion (upper end portion) of a driving rod 61 driven in, for example, the up-and-down directions vertically by an ascending and descending mechanism 60.

In the present embodiment, a conveyance robot 64 is provided on the supporter 62 of the substrate carry-in and carry-out mechanism 6, the substrate holder 11 discussed above is supported on the conveyance robot 64 so as to vertically move in the up-and-down directions, and the substrate carry-in and carry-out mechanism 6 is configured to transfer and receive the substrate holder 11 to and from the substrate-holder conveyance mechanism 3 by the conveyance robot 64.

In this case, as discussed later, the substrate carry-in and carry-out mechanism 6 is configured to transfer the substrate holder 11 to the substrate-holder introduction portion 30A of the forward path-side conveyance portion 33a of the substrate-holder conveyance mechanism 3 (this position is referred to as a “substrate holder transfer position”), and the substrate carry-in and carry-out mechanism 6 is configured to receive the substrate holder 11 from the substrate-holder ejection portion 30C of the return path-side conveyance portion 33c of the substrate-holder conveyance mechanism 3 (this position is referred to as a “substrate holder take-out position”).

A substrate carry-in and carry-out chamber 2A for carrying the substrate 10 into the vacuum chamber 2 and carrying the substrate 10 out of the vacuum chamber 2 is provided at, for example, an upper portion of the vacuum chamber 2.

The substrate carry-in and carry-out chamber 2A is provided at, for example, a position above the supporter 62 of the substrate carry-in and carry-out mechanism 6 discussed above through a communication opening 2B, and a lid portion 2a which can be opened and closed is provided at, for example, an upper portion of the substrate carry-in and carry-out chamber 2A.

As discussed later, the substrate 10 carried into the substrate carry-in and carry-out chamber 2A is transferred to and held by the substrate holder 11 on the conveyance robot 64 of the supporter 62 of the carry-in and carry-out mechanism 6, and a substrate 10A, on which a film is formed is taken out from the substrate holder 11 on the conveyance robot 64 of the supporter 62 of the carry-in and carry-out mechanism 6 into, for example, the atmosphere outside the vacuum chamber 2.

in the case of the present embodiment, a seal member 63, such as an O-ring, for isolating the substrate carry-in and carry-out chamber 2A and the environment in the vacuum chamber 2 from each other when the substrate 10 is carried in and out is provided on an upper edge portion of the supporter 62 of the substrate carry-in and carry-out mechanism 6.

In this case, the environment in the substrate carry-in and carry-out chamber 2A is isolated from the environment in the vacuum chamber 2 by raising the supporter 62 of the substrate carry-in and carry-out mechanism 6 toward the substrate carry-in and carry-out chamber 2A and closely adhering the seal member 63 on the supporter 62 to an inner wall of the vacuum chamber 2 so as to close the communication opening 2B.

A plurality of pairs of driving portions having a predetermined interval therebetween are provided on the two conveyance driving members 33, respectively, so as to protrude outward side from the conveyance driving members 33.

As shown in FIG. 3, in the present embodiment, a first driving portion 21 used as a driving portion for acceleration and a second driving portion 22 as another driving portion that is not used for acceleration, which are a pair of driving portions, are provided on the two conveyance driving members 33, respectively.

Here, both of the first driving portion 21 and the second driving portion 22 have a bar shape, and the first driving portion 21 and the second driving portion 22 are fixed to the conveyance driving member 33 so as to be perpendicular to a surface of the conveyance driving member 33. In short, the first and second driving portions 21 and 22 having the bar shape stand perpendicular to the surface of each conveyance driving member 33. As discussed later, the first and second driving portions 21 and 22 are provided to be in contact with first and second driven portions 12 and 13 of the substrate holder 11, and press to move the substrate holder 11 in the moving direction.

In addition, a pair of substrate holder support mechanisms 18 supporting the conveyed substrate holder 11 is provided between the first and second driving wheels 31. and 32, at inner positions of a pair of conveyance driving members 33 (see FIG. 2).

The conveyance driving member 33 has a ring shape, and is disposed such that a part of the conveyance driving member 33 is positioned on an upper side and the other part of the conveyance driving member 33 is positioned on a lower side. The conveyance driving member 33 is a bell or the like formed of a metal.

In the portion positioned on the upper side of the conveyance driving member 33, the substrate holder 11 is supported by the substrate holder support mechanisms 18 so as lo be positioned above the conveyance driving member 33, and in the portion positioned on the lower side of the conveyance driving member 33, the substrate holder 11 is supported by the substrate holder support mechanisms 18 so as to he positioned below the conveyance driving member 33.

The substrate holder support mechanisms 1S are formed of rotatable members, such as a plurality of rollers, and are provided in the vicinity of the conveyance driving member 33, respectively.

In the present embodiment, as shown in FIG. 3, forward path-side substrate holder support mechanisms 18a are provided in the vicinity of the forward path-side conveyance portion 33a of the conveyance driving member 33, and return path-side substrate holder support mechanisms 18c are provided in the vicinity of the return path-side conveyance portion 33c of the conveyance driving member 33. The forward path-side substrate holder support mechanisms 18c and the return path-side substrate holder support mechanisms 18c are disposed and configured to support both edge portions of a lower surface of the conveyed substrate holder 11.

The substrate holder 11 used in the present embodiment performs film formation on both surfaces of the substrate 10, and has a holder body 9. and the first and second driven portions 12 and 13 are provided on two side surfaces of the holder body 9, respectively. Openings are formed in the holder body 9, and the holder body 9 has a tray shape.

As shown in FIG. 2 and FIGS. 4(a) to 4c), the substrate holder 11 according to the present embodiment is formed in, for example, an elongated rectangular flat plate shape, and is configured to arrange and hold a plurality of substrates 10 having, for example, a rectangular shape in a row in a direction orthogonal to a longitudinal direction of the substrate holder 11, that is, a moving direction.

Here, openings 17 having the same shape as the size of each substrate 10 and having a size at which both surfaces of each substrate 10 are entirely exposed are provided in a portion of the substrate holder 11 where the plurality of substrates 10 are held.

In the portion holding the substrate, the substrate is configured to be held on the opening 17 by a holding member (not shown) in a state where both surfaces of the substrate are exposed, When the substrate 10 has a rectangular shape, the opening 17 also has a rectangular shape.

In the present embodiment, it is preferable in terms of a reduction in an installation area and improvement of processing ability that the substrate holder 11 is configured to arrange and hold the plurality of substrates 10 in a row in the direction orthogonal to the moving direction according to the present embodiment, but the embodiments are not particularly limited thereto.

However, in terms of improvement of film formation efficiency, it is also possible to arrange the plurality of substrates 10 in a plurality of rows in the direction orthogonal to the moving direction.

In this case, when the substrates 10 have a circular shape, for example, a staggered arrangement is adopted, such that it is possible to reduce an area of a portion on which the film is not formed on the substrate.

In addition, in the ease where the film formation efficiency is improved when the substrates 10 are arranged in the plurality of rows by a dimensional ratio between the substrate 10 and first and second shield portions 15 and 16 to be discussed later, it is also possible to arrange the substrates 10 in the plurality of rows.

The holder body 9 of each substrate holder 11 has a rectangular shape of which the longitudinal direction of the holder body 9 is arranged perpendicular to the moving direction, four side surfaces of the holder body 9 have a side surface facing a downstream side in the moving direction in which the substrate holder 11 moves, a side surface facing an upstream side in the moving direction, and two side surfaces facing lateral, and the first and second driven portions 12 and 13 are provided, respectively, on the two side surfaces facing lateral.

In one of the two side surfaces facing lateral, the first driven portion 12 is provided on a downstream side in the moving direction as compared with the second driven. portion 13. Therefore, in the two side surfaces, the first driven portion 12 is provided on a lead side of the holder body 9, and the second driven portion 12 is provided on a tail side of the holder body 9.

The first and second driven portions 12 and 13 have a bar shape, and are provided perpendicular to the side surfaces of the holder body 9 so as to extend in the horizontal direction.

A gap is provided between the two conveyance driving members 33, the holder body 9 is positioned between the two conveyance driving members 33, and the first and second driven portions 12 and 13 are disposed on the two conveyance driving members 33, respectively. Here, the first and second driven portions 12 and 13 are not in contact with the two conveyance driving members 33, and in a state where the first and second driven portions 12 and 13 are not in contact with the first driving portion 21 or the second driving portion 22, the substrate holder 11 is not moved by the moving conveyance driving members 33.

A cross-sectional shape of each of the first and second driven portions 12 and 13 is a circular shape having a central axis extending in the longitudinal direction of the substrate holder 11, and as discussed later, the first and second driven portions 12 and 13 are in contact with the first and second driving portions 21 and 22 provided on the conveyance driving members 33 and are pressed by the first or second driving portion 21 or 22, and the substrate holder 11 is configured to move toward the moving direction by a force at which the first and second driven portions 12 and 13 are pressed.

The two conveyance driving members 33 are configured to move at the same speed, the second driving portions 22 each provided on the two conveyance driving members 33 are simultaneously in contact with the first driven portions 12 each provided on the two side surfaces of one substrate holder 11, and the first driving portions 21 each provided on the two conveyance driving members 33 are simultaneously in contact with the second driven portions 13 each provided on the two side surfaces of one substrate holder 11.

When the substrate holder 11 is moved by the conveyance driving member 33, shield portions are provided, respectively, on an end portion of the upstream side and an end portion of the downstream side in the moving direction of the substrate holder 11. Here, the shield portion provided on the end portion of any one of the upstream side and the downstream side is defined as a first shield portion (shield portion) 15, and the shield portion provided on the end portion of the other of the upstream side and the downstream side is defined as a second shield portion (shield portion) 10.

The first and second shield portions 15 and 16 are provided in order to shield a flying film formation material (sputtering particles), and are provided to protrude from both end portions of a moving direction side toward the moving direction, respectively, over the entire region of the longitudinal direction of the substrate holder 11.

In the present embodiment, as shown in FIG. 4(c), the first shield portion 15 provided on an end portion of the substrate holder 11 where the first driven portion 12 is provided, is trade protrude on a lower surface side of the substrate holder 11 toward, for example, the downstream side in the moving direction, and the second shield portion 16 provided on an end portion of the substrate holder 11 where the second driven portion 13 is provided, is made protrude on an upper surface side of the substrate holder 11 toward, for example, the upstream side in the moving direction.

In the case where the plurality of substrate holders 11 are conveyed in a state where they are close to each other, for example, as shown in FIG. 4(c), the first shield. portion 15 of one of two substrate holders 11 adjacent to each other becomes a lower side and the second shield portion 16 of the other of the two substrate holders 11 becomes an upper side (alternatively, the first shield portion 15 of one of the two substrate holders 11 becomes an upper side, and the second shield portion 16 of the other of the two substrate holders 11 becomes a lower side), such that the first and second shield portions 15 and 16 overlap each other.

A gap may be provided between the first and second shield portions 15 and 16 overlapping each other.

Here, the “two substrate holders 11 adjacent to each other” mean that the other substrate holder 11 is not positioned between the two substrate holders 11 and the same applies to a case where other members are adjacent to each other.

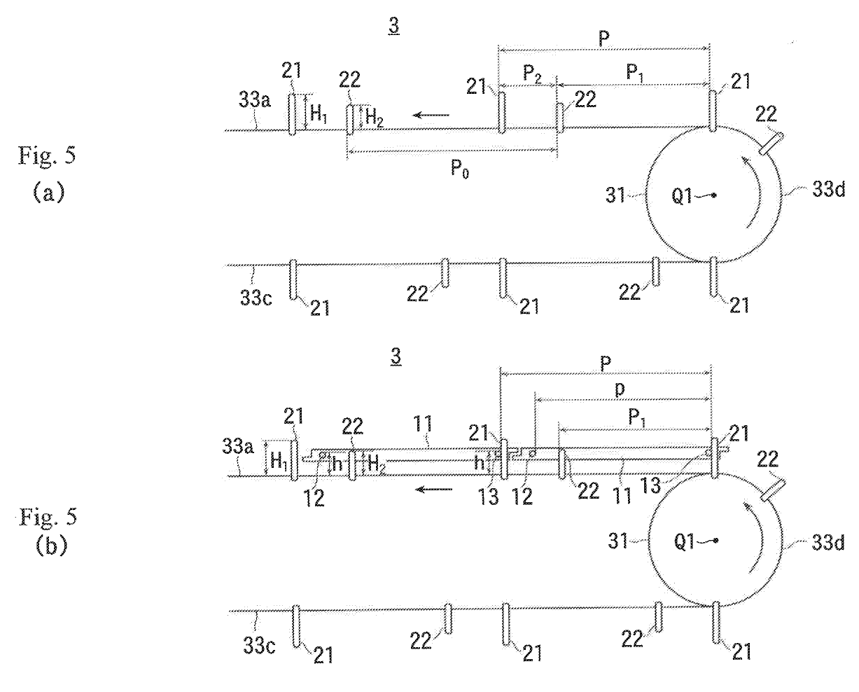

FIGS. 5(a) and 5(b) are explanatory diagrams showing a relationship between dimensions of the first and second driving portions 211 and 22 in the substrate-holder conveyance mechanism 3 and a dimension of the substrate holder 11.

In the case of the present embodiment, a dimensional relationship between the respective portions will be discussed using a case in the forward path-side conveyance portion 33a as an example, but because dimensional relationships between the respective portions are the same as each other in the forward path-side conveyance portion 33a which is the first conveyance portion, and the return path-side conveyance portion 33c which is the second conveyance portion, the dimensional relationship in the forward path-side conveyance portion 33a is also applied to the return path-side conveyance portion 33c.

As shown in FIGS. 5(a) and 5(b), in a plurality of the first driving position 21, a height (distance from a surface of the conveyance driving member 33 positioned in the forward path-side conveyance portion 33a to an upper end of the first driving portion 21) (the same applies to a “height” in the following) H₁ of a plurality of first driving portions 21 positioned in the forward path-side conveyance portion 33a is higher than a height h of the first and second driven portions 12 and 13 of the conveyed substrate holder 11.

All of first pitches P, which are distances between centers of first driving portions 21 and 21 adjacent to each other in one conveyance driving member 33 when the conveyance driving member 33 is disposed in a planar shape, are set to be the same as each other. The distance between the centers is equal to a distance between surfaces facing a downstream side and a distance between surfaces facing an upstream side. The same applies to the following.

In the case of the present embodiment, the first pitch P is set to be greater than a driven portion pitch p which is a distance between the first and second driven portions 12 and 13 of one substrate holder 11, as shown in FIG. 5(b).

When the substrate holder 11 in the forward path-side conveyance portion 33a is moved to the downstream side in the moving direction by bringing the first driving portions 21 and 21 adjacent to each other in one conveyance driving member 33, respectively, into contact with surfaces of the upstream side in the moving direction of the second driven portions 13 and 13 of the substrate holders 11 positioned adjacent to each other and moving the first driving portions 21 and 21 and pressing the second driven portions 13 and 13, the substrate holders 11 and 11 adjacent to each other are lined, and conveyed in a state where they are close to each other.

Here, the first pitch P, the driven portion pitch p, and the dimension of each substrate holder 11 (the dimensions of the first and second shield portions 15 and 16) are set such that when the end portion of the upstream side in the moving direction of the substrate holder 11 positioned the downstream side in the moving direction and the end portion of the downstream side in the moving direction of the substrate holder 11 positioned on the upstream side in the moving direction are close to each other, and the first shield portion 15 of the one substrate holder 11 at the upstream side in the moving direction and the second shield portion 16 of the other substrate holder 11 at the downstream side that are adjacent each other are overlapped each other with gap between them such that the first shied portion 15 is positioned lower side and the second shield portion 16 is positioned upper side (see FIG. 4(c)).

On the other hand, a height (a distance of a top portion with respect to the forward path-side conveyance portion 33a) H₂ of a plurality of second driving portions 22 positioned in the forward path-side conveyance portion 33a is set to be higher than the height h of the first and second driven portions 12 and 13 of the substrate holder 11, and to be lower than the height H₁ of the first driving portions 21.

In one conveyance driving member 33, the first driving portions 21 and the second driving portions 22 are alternately arranged, and a second pitch P₀ which is a distance between the second driving portions 22 and 22 adjacent to each other when the conveyance driving member 33 is disposed in the planar shape is set to be the same as the first pitch P as discussed above.

Then, in one conveyance driving member 33, the first driving portions 21 are disposed adjacent to the second driving portion 22, respectively, on the upstream side and the downstream side in the moving direction of the second driving portion 22, and an upstream side pitch P₁, which is a distance between the second driving portion 22 and the first driving portion 21 adjacent to the second driving portion 22 on the upstream side in the moving direction when the conveyance driving member 33 is disposed in the planar shape, is set to he greater than a downstream side pitch P₂, which is a distance between the second driving portion 22 and the first driving portion 21 adjacent to the second driving portion 22 on the downstream side in the moving direction when the conveyance driving member 33 is disposed in the planar shape (see FIG. 5(a)).

In more detail, the second pitch P₀ is assumed to be a distance between surfaces of the first and second driving portions 21 and 22 facing a downstream of a moving direction, and the driven portion pitch p is assumed to be a distance between surfaces of the first and second driven portion 12 and 13 facing an upstream of the moving direction. The upstream side pitch P₁ is set to be smaller than the driven portion pitch p (see FIG. 5(b)).

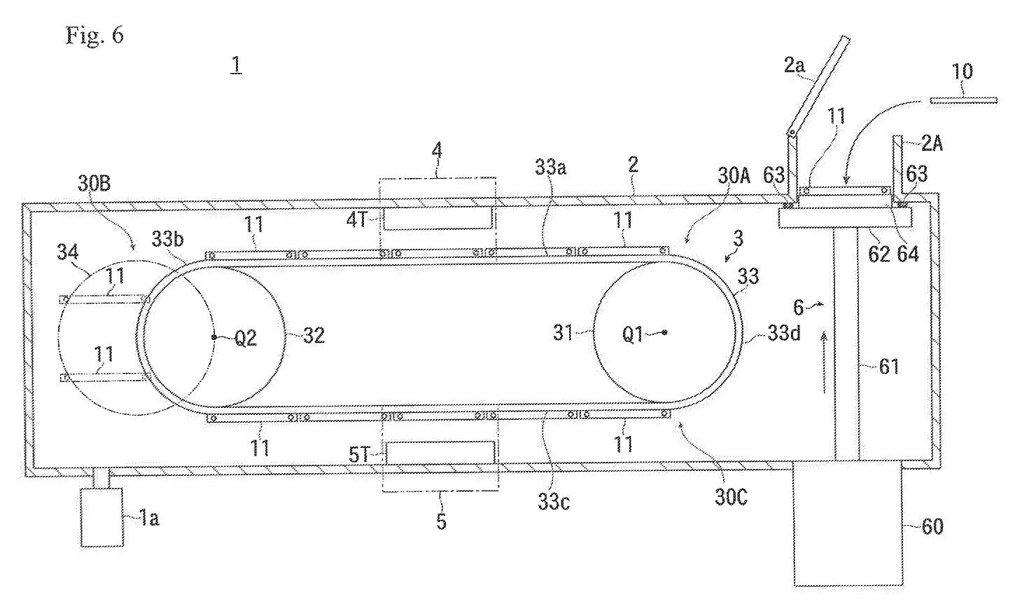

Hereinafter, operations of the film formation apparatus 1 according to the present embodiment and a film formation method using the film formation apparatus 1 will be discussed with reference to FIGS. 6 to 18.

In the present embodiment, first, as shown in FIG. 6, in a state of isolating the environment in the substrate carry-in and carry-out chamber 2A from the environment in the vacuum chamber 2 by closely adhering the seal member 63 on the supporter 62 of the substrate carry-in and carry-out mechanism 6 to the inner wall of the vacuum chamber 2, the pressure is mode up to the atmospheric pressure, and the lid portion 2a of the substrate carry-in and carry-out chamber 2A is then opened.

Then, the substrate 10 is mounted on and held by the substrate holder 11 on the conveyance robot 64 of the supporter 62 of the substrate carry-in and carry-out mechanism 6 using a transfer robot (not shown).

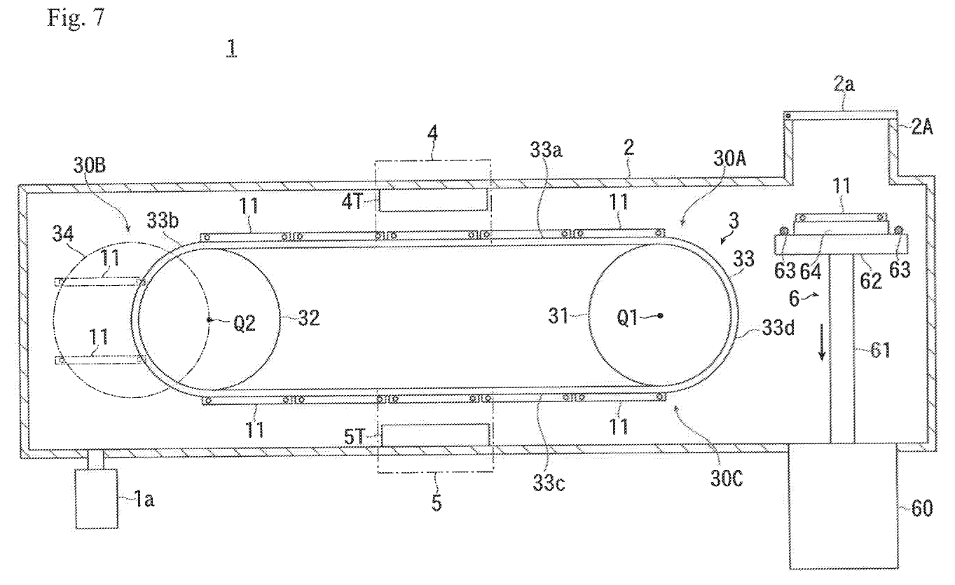

As shown in FIG. 7, the lid portion 2a of the substrate carry-in and carry-out chamber 2A is closed, vacuum exhaust is performed until a pressure arrives at a predetermined pressure, and the supporter 62 of (the substrate carry-in and carry-out mechanism 6 is lowered to the substrate holder transfer position to allow the substrate holder 11 to be positioned at the same height as that of the forward path-side conveyance portion 33a of the conveyance driving member 33.

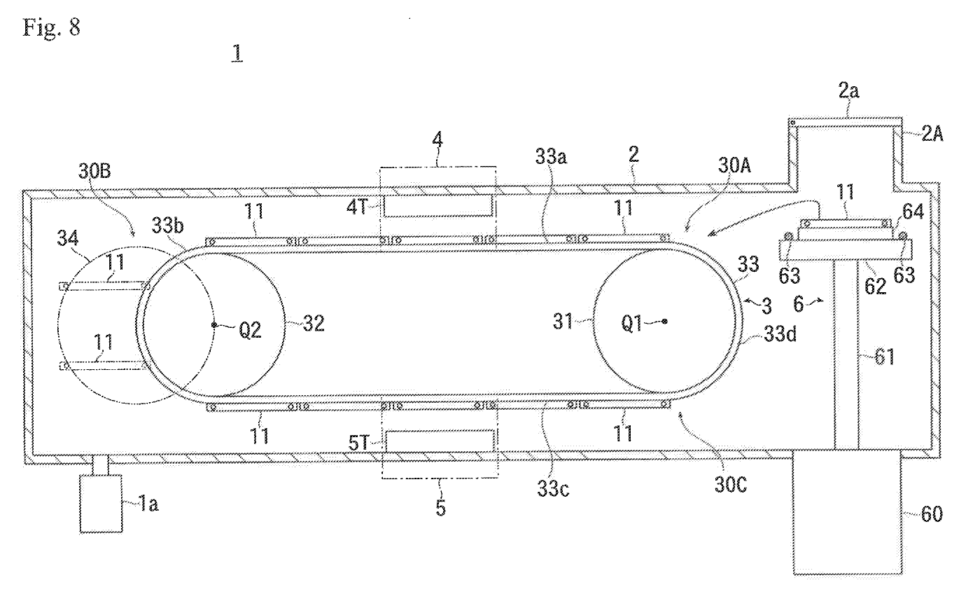

Further, as shown in FIG. 8, the substrate holder 11 is displaced on the substrate-holder introduction portion 30A of the substrate-holder conveyance mechanism 3 by the conveyance robot 64 provided on the supporter 62 of the substrate carry-in and carry-out mechanism 6.

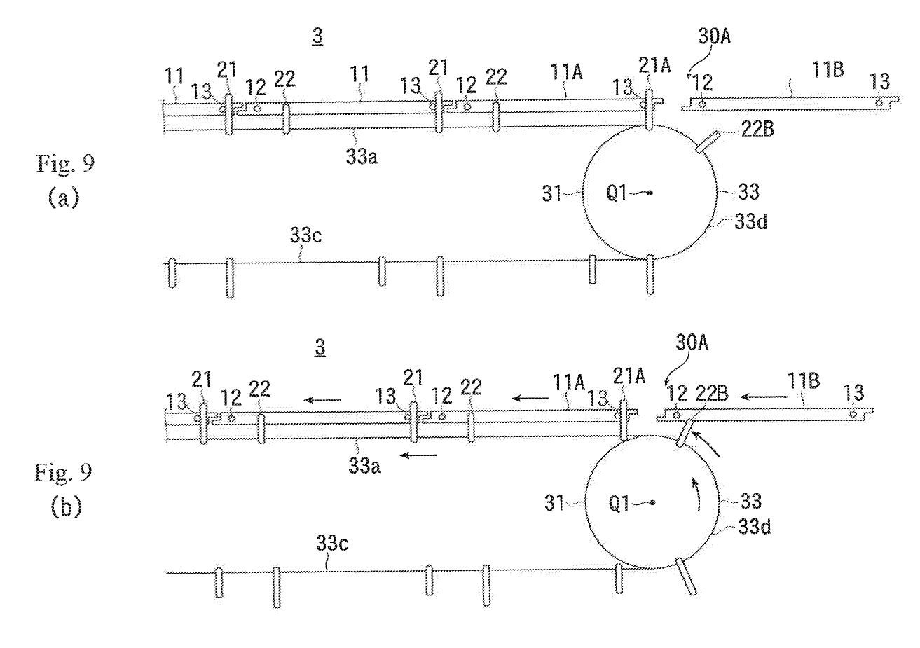

An operation of transferring the substrate holder 11 to the substrate-holder conveyance mechanism 3 in the present embodiment will be discussed with reference to FIGS. 9(a) to 12(b).

Actually, an operation of transferring the substrate holder 11 to the substrate carry-in and carry-out mechanism 6 is also performed simultaneously with such a transfer operation. However, in the present specification, in order to facilitate the understanding, the operation of transferring the substrate holder 11 to the substrate carry-in and carry-out mechanism 6 will be discussed later.

Hereinafter, a process in which a substrate holder 11B adjacent to and following a substrate holder 11A positioned in the conveyance driving member 33 positioned in the forward path-side conveyance portion 33a is moved from the substrate carry-in and carry-out mechanism 6 to the first conveyance portion 33a will be discussed.

First, the following substrate holder 11B is arranged on the substrate-holder introduction portion 30A of the substrate-holder conveyance mechanism 3 using the conveyance robot 64 of the substrate carry-in and carry-out mechanism 6, as shown in FIG. 9(a).

The substrate holder 11B disposed in the substrate-holder introduction portion 30A is stopped at a place where the forward path-side conveyance portion 33a is extended to an upstream side, and a first driven portion 12 of the substrate holder 11B is positioned on a downward side in a moving direction as compared with a second driven portion 13.

In this case, the substrate holder 11A and the following substrate holder 11B positioned in the substrate-holder introduction portion 30A are spaced apart from each other, such that the shield portions 15 and 16 do not overlap each other.

The first driving wheel 31 rotates around the rotation axis Q1 below the following substrate holder 11B positioned in the substrate-holder introduction portion 30A, and a portion of the conveyance driving member 33 in contact with the first driving wheel 31 rotationally moves at the same rotational speed as that of the first driving wheel 31. The second driving portion 22B provided on the conveyance driving member 33 that rotationally moves also rotationally moves, and the second driving portion 22B moves upward by the rotational movement, as shown in FIG. 9(b).

When the first driving wheel 31 further rotates, and when the conveyance driving member 33 of a portion on which the second driving portion 22B is provided is spaced apart horn the first driving wheel 31, the second driving portion 22B starts a linear movement along a conveyance path of the forward path-side conveyance portion 33a.

The second driving portion 22B protrudes outward in a rotation direction during the rotational movement, und protrudes upward during the linear movement.

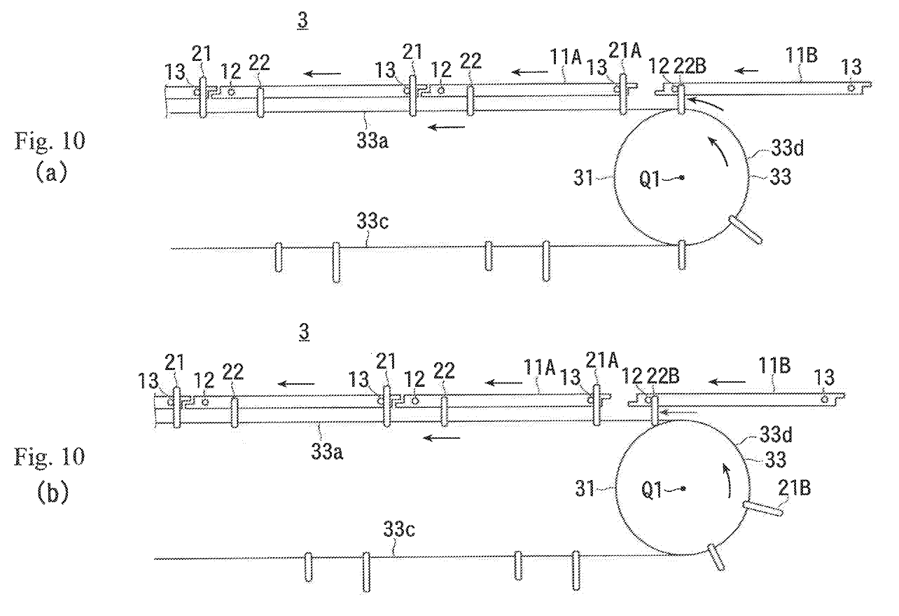

When the first driven portion 12 of the substrate holder 11B positioned in the substrate-holder introduction portion 30A is positioned on an upstream side as compared with a position directly above the rotation axis Q1, the second driving portion 22B during rotation is in contact with the first driven portion 12, and when the first driven portion 12 is positioned on a downstream side as compared with the position directly above the rotation axis Q1, the second driving portion 22B changed from the rotational movement into the linear movement is in contact with the first driven portion 12. When the first driven portion 12 is positioned directly above the rotation axis Q1, the second driving portion 22B at the time of switching from the rotational movement to the linear movement is in contact with the first driven portion 12 (see FIG. 10(a)).

In either case, a surface oi the second driving portion 22B facing the downstream side in the moving direction is in contact with a surface of the first driven portion 12 facing the upstream side in the moving direction.

When the second driving portion 22B rotationally moves or linearly moves in a state where the second driving portion 22B is in contact with the first driven portion 12, the first driven portion 12 is pressed toward the downstream side in the moving direction by the second driving portion 22B, and the substrate holder 11B moves to the downstream side in the moving direction.

When the linear movement is continued, as shown in FIG. 10(b), the front edge of the substrate holder 11B enters the forward path-side conveyance portion 33a and linearly moves in the forward path-side conveyance portion 33a. The preceding substrate holder 11A also moves together, and the second driven portion 13 of the preceding substrate holder 11A and the first driven portion 12 of the following substrate holder 11B are linearly moved in a state where they are spaced apart from each other by a distance of the downstream side pitch P₂.

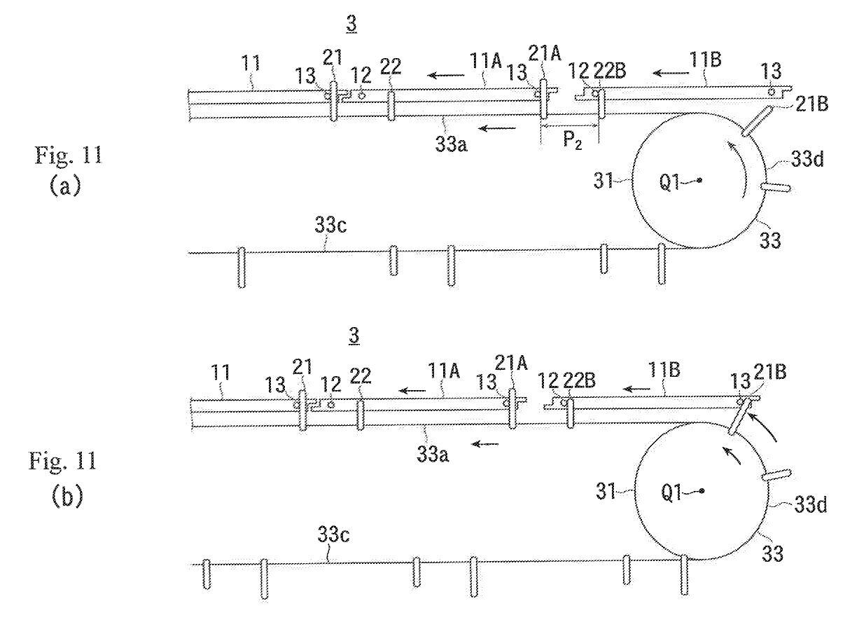

In this state, at the upstream side in the moving direction as compared with the second driving portion 22B which moves the substrate holder 11B, the first driving portion 21B adjacent to the second driving portion 22B rotationally moves by the rotation of the first driving wheel 31 to move upward, such that the first driving portion 21B approaches the second driven portion 13, as shown in FIG. 11(a).

The first driving portion 21B is perpendicular to the conveyance driving member 33 even during the rotational movement, and when the first driving wheel 31 rotates about the rotation axis Q1, an upper end of the first driving portion 21B rotates along a concentric circle having a greater diameter than the first driving wheel 31.

Therefore, a rotational movement speed of the upper end of the first driving portion 21B is higher than the rotational movement speed of the conveyance driving member 33 in contact with the first driving portion 21.

When the second driving portion 22B linearly moves, the upper end of the first driving portion 21B rotates and moves upward while being facing the upstream side in the moving direction of the first conveyance portion 33a, and a distance between a ratio of the upper end of the first driving portion 21B moving upward while facing obliquely upward. and a portion of the second driving portion 22B in contact with the first driven portion 12 becomes greater than the upstream side pitch P₁.

The first and second driven portions 12 and 13 are positioned in a reference plane, which is the same horizontal plane. When the first driving portion 21B is raised by the rotation, such that an upper end portion of the first driving portion 21B intersects with the reference surface, the substrate holder 11B is moving by pressing of the second driving portion 22B in a state where the second driven portion 13 is positioned on the upstream side as compared with the position directly above the central axis Q1 of the first driving wheel 31, and the second driven portion 13 is positioned between the upper end portion of the first driven portion 12 and an extension of the first driving portion 21B,

Because a movement speed of the first driving portion 21B in the horizontal direction is higher than the movement speed of the second driven portion 13, the first driving portion 21B catches up with the second driven portion 13, and a surface of the downstream side of the upper end portion of the first driving portion 21B is in contact with a surface of the upstream side of the second driven portion 13 (FIG. 11(b)).

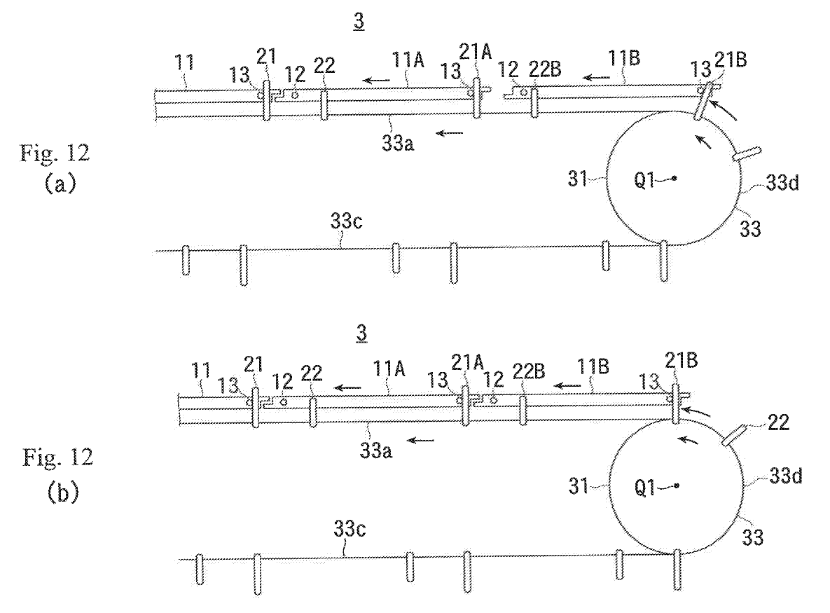

Further, when the first driving portion 21B is raised while being further rotated, the second driven portion 13 is pressed in the horizontal direction by the first driving portion 21B at a speed higher than a movement speed of the second driving portion 22B, such that the first driven portion 12 of the substrate holder 11B is spaced apart from the second driving portion 22B with which it was in contact (see FIG. 12(a)).

Before the first driving portion 21B passes through the position directly above the central axis Q1 of the first driving wheel 31, a contact portion between the first driving portion 21B and the second driven portion 13 moves in the horizontal direction at a speed higher than the movement speed of the second driving portion 22B, such that the following substrate holder 11B approaches the preceding substrate holder 11A. The contact portion between the first driving portion 21B and the second driven portion 13 moves from an upper end side to a base side during a period in which the first driving portion 21B rotationally moves (FIG. 12 (b)).

When the first driving portion 21B arrives at the position directly above the central axis Q1 of the first driving wheel 31, the rotational movement of the first driving portion 21B ends, and the first driving portion 21B linearly moves. The movement speed of the first driving portion 21B becomes equal to the movement speed of the second driving portion 22B.

When the first driving portion 21B is positioned on the upstream side as compared with the position directly above the central axis Q1 of the first driving wheel 31, a distance between the preceding second driving portion 22B and the following first driving portion 23B is shortened by the rotation of the first driving wheel 31. However, when the first driving portion 21B arrives at the position directly above the central axis Q1 of the first driving wheel 31, the distance between the preceding second driving portion 22B and the following first driving portion 21B becomes a size of the upstream side pitch P₁, and the distance of the upstream side pitch P₁ is maintained during a period in which the second driving portion 22B and the first driving portion 218 linearly move.

Through the processes discussed above, the operation of introducing the following substrate holder 11B ends.

The plurality of first driving portions 21 provided in the forward path-side conveyance portion 33a of the conveyance driving member 33 are in contact with the second driven portions 13 of the substrate holders 11, respectively, and the forward path-side conveyance portion 33a is moved to the downstream side (first moving direction) in the moving direction toward the second driving wheel 32 (see FIG. 8), such that the respective substrate holders 11 are conveyed by a driving force from the first driving portion 21 in a slate where the substrate holders 11 are close to each other.

Each substrate holder 11 moves along a moving path in the forward path-side conveyance portion 33a of the conveyance driving member 33 by an operation of the substrate-holder conveyance mechanism 3, and passes through the first film formation region 4 (See FIG. 1).

Each substrate holder 11 approaches the second driving wheel 32 when moving in the forward path-side conveyance portion 33a.

Therefore, the first driving portions 21 discussed above are in contact with and pressed against the second driven portions 13 of the plurality of substrate holders 11 supported by the forward path-side substrate holder support mechanisms 18a, such that the substrate holders 11 move on the forward path-side conveyance portion 33a of the conveyance driving member 33 toward the turning conveyance portion 30B in a state where they are close to each other at a predetermined interval (see FIG. 3).

When the substrate holder 11 passes through a position of the first film formation region 4, film formation is performed on both surfaces of the substrate 10 held by the substrate holder 11 by sputtering by a first sputtering source 4T positioned above the substrate holder 11 (see FIGS. 1 and 2).

Then, each substrate holder 11 is moved from the forward path-side conveyance portion 33a to the turning conveyance portion 30B and is moved from the turning conveyance portion 30B to the return path-side conveyance portion 33c, while maintaining a state where a surface of each substrate holder 11 facing upward during movement of each substrate holder 11 in the first conveyance portion 33a faces upward and a surface of each substrate holder 11 facing downward during the movement of each substrate holder 11 in the first conveyance portion 33a faces downward in the turning conveyance portion 30B (see FIG. 1).

In the substrate holder 11 that is moving in the turning conveyance portion 30B, the first driven portion 12 is positioned on an upstream side of the second moving direction, which is a conveyance moving direction in the return path-side conveyance portion 33c, and the second driven portion 13 is positioned on a downstream side of the second moving direction.

When the substrate holder 11 is moved from the turning conveyance portion 30B to the return path-side conveyance portion 33c, the first driving portion 21 is brought into contact with the second driven portion 13 of the substrate holder 11 positioned in the fuming conveyance portion 30B to linearly move the substrate holder 11 by the first driving portion 21.

When the first driving portion 21 rotationally moves while being in contact with the second driven portion 13 of the following substrate holder 11 to move the substrate holder 11, the substrate holder 11 moves at a speed higher than the speed of the preceding substrate holder 11 as in the above-discussed case of the forward path-side conveyance portion 33a.

The respective substrate holders 11 move toward the substrate-holder ejection portion 30C on the return path-side conveyance portion 33c of the conveyance driving member 33 in a state where they are close to each other at a predetermined interval (see FIG. 3).

Each substrate holder 11 passes through the second film formation region 5 before arriving at the substrate-holder ejection portion 30C.

In this case, in the substrate-holder conveyance mechanism 3 according to the present embodiment, as discussed above, in the substrate holder 11 moved from the forward path-side conveyance portion 33a to the return path-side conveyance portion 33c via the turning conveyance portion 30B, the surface of the substrate holder 11 facing upward in the forward path-side conveyance portion 33a faces upward, and the surface or the substrate holder 11 facing downward in the forward path-side conveyance portion 33a faces downward.

As discussed above, because upward and downward directions of the substrate holder 11 are not changed when the substrate holder 11 passes through the turning conveyance portion 30R, when the substrate holder 11 passes through a position of the second film formation region 5, a surface on which a film is not formed by the first sputtering source 4T. of the substrate 10 held by the substrate holder 11 faces the second sputtering source 5T.

Therefore, when the substrate holder 11 passes through the second sputtering source 51 disposed under the substrate holder 11 while the second sputtering source 5T performs sputtering, the film is formed on a back surface of the substrate 10 held by the substrate holder 11 (see FIG. 1).

After the substrate holder 11 arrives at the substrate-holder ejection portion 30C, an operation of transferring the substrate holder 11 to the substrate carry-in and carry-out mechanism 6 is performed.

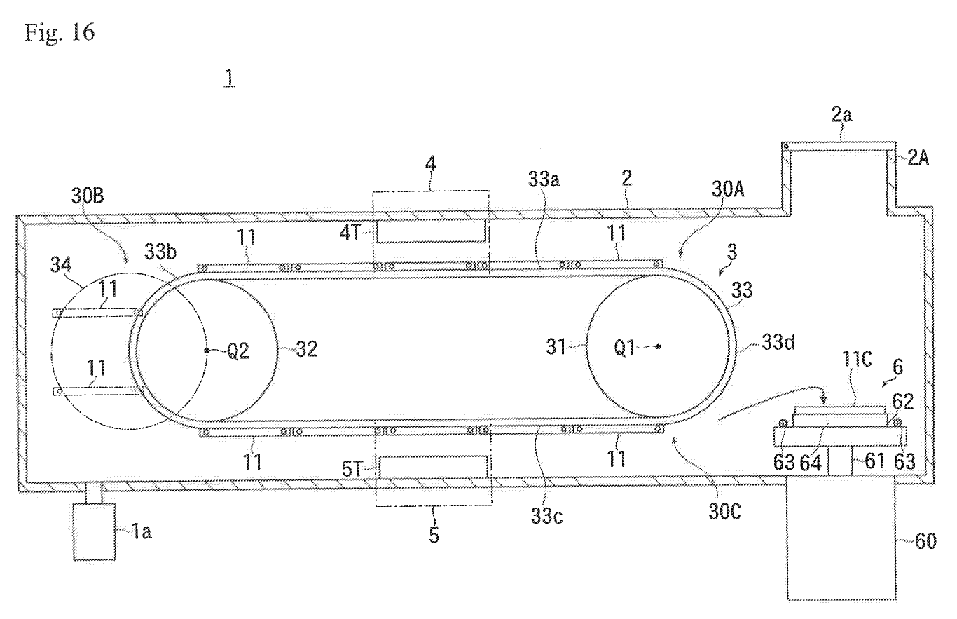

In this case, the supporter 62 of the substrate carry-in and carry-out mechanism 6 is disposed at the substrate holder take-out position (see FIG. 16).

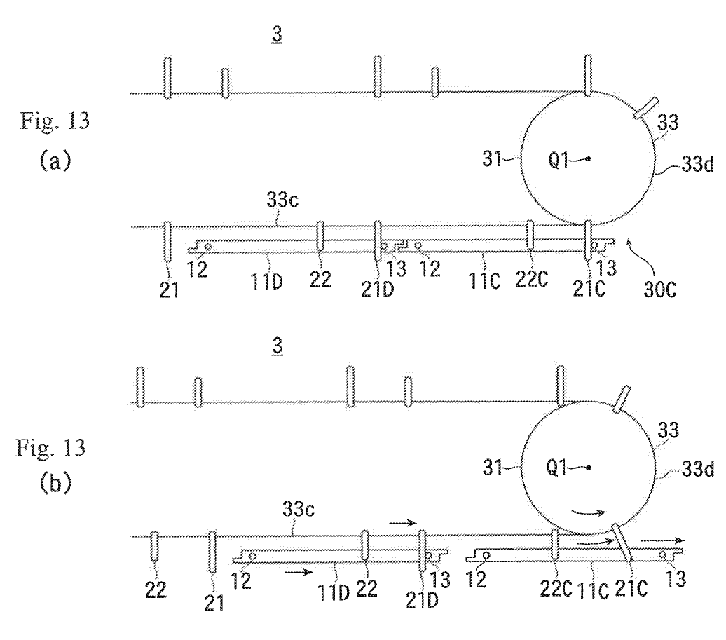

Hereinafter, an operation in which the substrate holder 11 is transferred lo the substrate carry-in and carry-out mechanism 6 will be discussed with reference to FIGS. 13(a) to 15(b).

Actually, an operation of transferring the substrate holder 11 to the substrate-holder conveyance mechanism 3 is also performed at the time of such a transfer operation. However, because the operation is as discussed above, in order to facilitate the understanding, only the operation of transferring the substrate holder 11 to the substrate carry-in and carry-out 6 will hereinafter be discussed.

FIG. 13(a) shows a state where a substrate holder 11C that is to be transferred to the substrate carry-in and carry-out mechanism 6 is disposed on the substrate-holder ejection portion 30C of the substrate-holder conveyance mechanism 3.

Hereinafter, a ease where the preceding substrate holder 11C (hereinafter, referred to as the “preceding side substrate holder 11C”) disposed on the return path-side conveyance portion 33c of the conveyance driving member 33 is separated from the following substrate holder 11D (hereinafter, referred to as the “following side substrate holder 11, and is transferred to the substrate carry-in and carry-out mechanism 6 will be discussed as an example.

In the stale shown in FIG. 13(a), two first driving portions 21C and 21D provided in the return path-side conveyance portion 33c of the conveyance driving member 33 are, respectively, in contact with upstream side portions in a moving direction of second driven portions 13 of the preceding side substrate holder 11C and the following side substrate holder 11D, and the return path-side conveyance portion 33c is moved in a second moving direction toward the first driving wheel 31, such that the preceding side substrate holder 11C and the following side substrate holder 11D are conveyed in the second moving direction by driving forces from the preceding side first driving portion 21C and the following side first driving portion 21D, respectively.

In this case, the preceding side first driving portion 21C which is a driving portion for acceleration in contact with the second driven portion 13 of the preceding side substrate holder 11C, is positioned in a vertical direction below the first driving wheel 31. and the preceding side substrate holder 11C and the following aide substrate holder 11D are in a state where they are close to each other.

When the substrate-holder conveyance mechanism 3 is operated to rotate the first driving wheel 31 from this state, and the preceding side first driving portion 21C and the following side first driving portion 21D provided in the return path-side conveyance portion 33c of The conveyance driving member 33 are moved in the second moving direction along an arc of the first driving wheel 31 as shown in FIG. 13(b), the preceding side substrate holder 11C and the following side substrate holder 11D are conveyed in the second moving direction by their respective driving forces.

In this case, because the preceding side first driving portion 21C rotationally moves while being in contact with the second driven portion 13 of the preceding side substrate holder 110 on a concentric circle having a diameter greater than the diameter of the first driving wheel 31, a speed at which the preceding side first driving portion 21C moves the second driven portion 13 of the preceding side substrate holder 11C in the second moving direction becomes higher than a speed at which the following side first driving portion 21D moves the second driven portion 13 of the following side substrate holder 11D in the second moving direction. As a result, an end portion al an upstream side in the moving direction of the preceding side substrate holder 11C is separated from an end portion of a downstream side in the moving direction of the following side substrate holder 11D.

Then, as the preceding side first driving portion 21C is in a state where it is inclined from the vertical direction in accordance with the rotation of the first driving wheel 31, the preceding side first driving portion 21C and the second driven portion 13 of the preceding side substrate holder 11C are not in contact with each other as shown in FIG. 13(b). By the movement, the preceding side substrate holder 11C loses a propulsive force, therefore, the preceding side substrate holder 11C is moved in the second moving direction by the conveyance robot 64 of the substrate carry-in and carry-out mechanism 6 to be spaced apart from the following side substrate holder 11D.

Then, an operation of taking out the preceding side substrate holder 11C using the conveyance robot 64 of the substrate carry-in and carry-out mechanism 6 is performed.

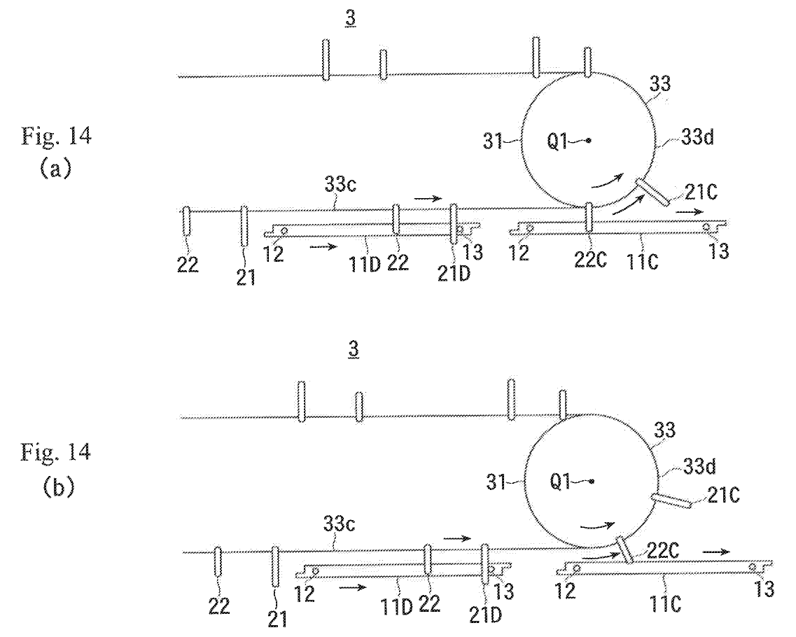

Further, when an operation of the conveyance driving member 33 is continued, the preceding side first driving portion 21C moves upward along the arc of the first driving wheel 31 together with the conveyance driving manner 33. Therefore, the preceding side substrate holder 11C is moved in the second moving direction using the conveyance robot 64 discussed above such that a tip portion of the preceding side first driving portion 21C is not in contact with the second driven portion 13 of the preceding side substrate holder 11C, as shown in FIG. 14(a).

Reference numeral 33d denotes a driving portion turning portion that moves the first and second driving portion 21 and 22 passing through the second film formation region 5 together with portions of the conveyance driving member 33 provided with the first and second driving portions 21 and 22 along the return path-side conveyance portion 33c, from the return path-side conveyance portion 33c to the forward path-side conveyance portion 33a, and the first and second driving portions 21 and 22 move upward along the arc of the first driving wheel 31.

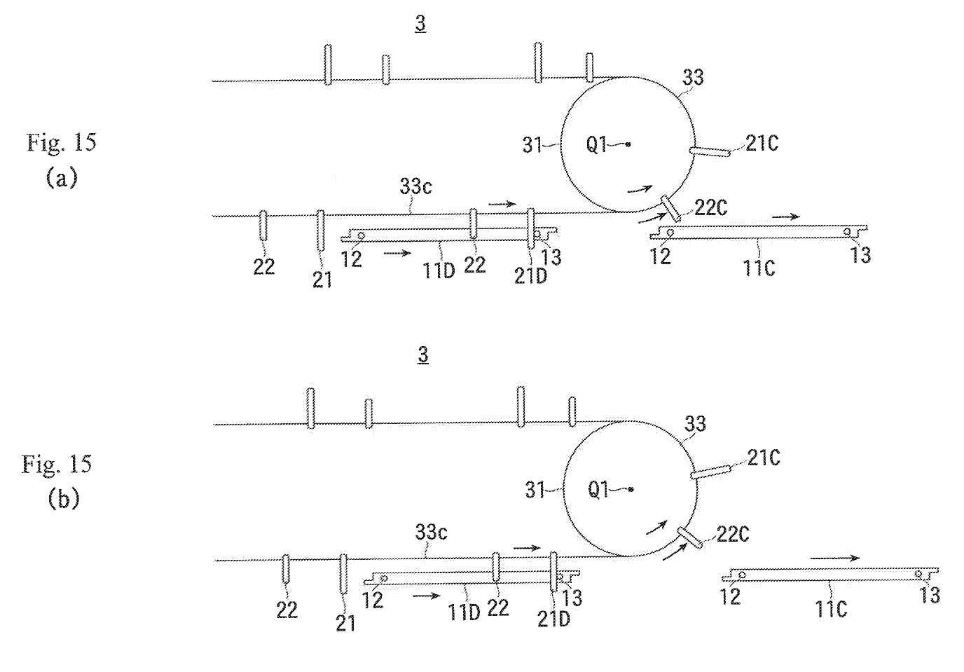

When the operation of the conveyance driving member 33 is continued, the second driving portion 22C moves upward along the arc of the first driving wheel 31 together with the conveyance driving member 33, as shown in FIG. 14(b). However, in this case, because the following second driving portion 22C approaches the first driven portion 12 of the preceding substrate holder 11C (see FIG. 15(a)), the preceding side substrate holder 11C is moved in the second moving direction using the conveyance robot 64 discussed above such that a tip portion of the preceding second driving portion 22C is not in contact with the first driven portion 12 of the preceding side substrate holder 11C, as shown in FIG. 15(b).

Through the processes discussed above, the operation of taking out the preceding side substrate holder 11C ends.

The substrate holder 11 taken out by the process discussed above is disposed together with (he conveyance robot 64 on the supporter 62 as shown in FIG. 16.

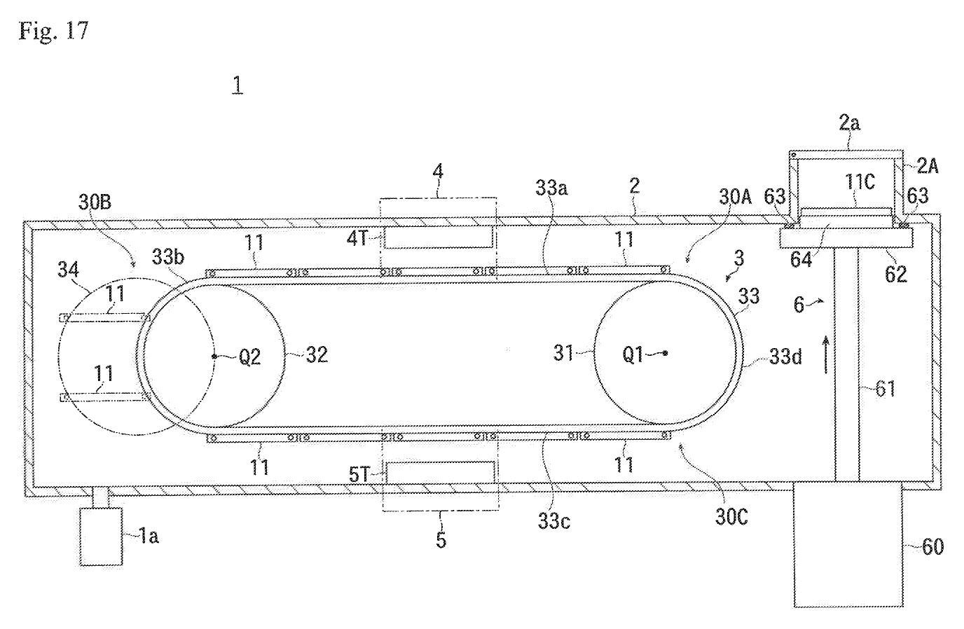

Then, as shown in FIG. 17, in a state of isolating the environment in the substrate carry-in and carry-out chamber 2A from the environment in the vacuum chamber 2 by raising the supporter 62 of the substrate carry-in and carry-out mechanism 6 and closely adhering the seal member 63 on the supporter 62 to the inner wall of the vacuum chamber 2, the pressure is made up to the Atmospheric pressure.

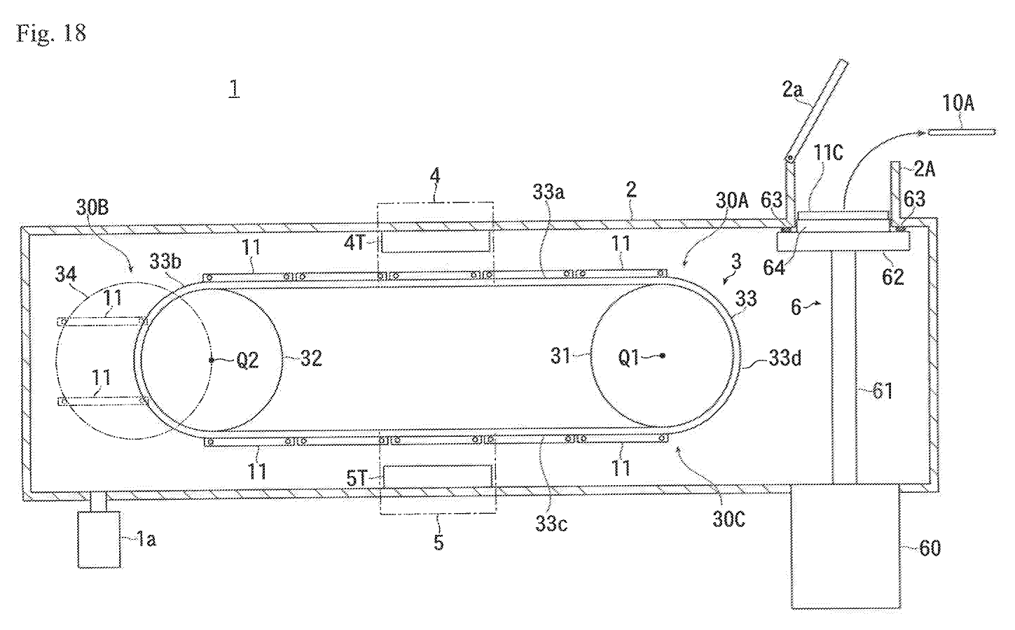

As shown in FIG. 18, the lid portion 2a of the substrate carry-in and carry-out chamber 2A is opened, and the substrate 10A on which the film is formed is taken out from the substrate holder 11 into the air atmosphere by using a conveyance robot (not shown).

Then, returning to a state shown in FIG. 6, the operations discussed above are repeated, such that film formation is performed on both surfaces of each of the plurality of substrates 10.

In the present embodiment discussed above, in the vacuum chamber 2 in which a single vacuum environment is formed, the conveyance path is formed such that a shape thereof projected on a vertical plane is a continuous ring shape, and the substrate-holder conveyance mechanism 3 that conveys the plurality of substrate holders 11 along the conveyance path in a slate where the plurality of substrate holders keep horizontal is provided. Therefore, a small film formation apparatus 1 can be provided.

In addition, in the present embodiment, the substrate-holder conveyance mechanism 3 has a plurality of first and second driving portions 21 and 22 that are in contact with the first and second driven portions 12 and 13 each provided on the plurality of substrate holders 11 and press and move the substrate holder 11 in the moving direction, and the first and second driving portions 21 and 22 are configured to convey the substrate holders 11 adjacent to each other to the first and second film formation regions 4 and 5 in a state where an end portion at the upstream side in the moving direction of the substrate holder 11 at the downstream side in the moving direction and an end portion at the downstream side in the moving direction of the substrate holder 11 of the upstream side in the moving direction are close to each other. Therefore, it is possible to dispose as many substrate holders 11 as possible in the conveyance path without performing a complicated control. As a result, it is possible to provide the film formation apparatus 1 that has a simple configuration and efficiently performs film formation.

Further, because an interval between the plurality of substrate holders 11 can be made narrower than the interval in the conventional technology, it is possible to efficiently use a film formation material without wasting the film formation material, and an amount of the film formation material passing between the substrate holders 11 can be reduced. Therefore, it is possible to reduce an amount of the film formation material attached to the inside of the vacuum chamber 2, and it is possible to prevent contamination of the film formation material in the vacuum chamber 2.

Furthermore, the substrate-holder conveyance mechanism 3 according to the present embodiment has the forward path-side conveyance portion 33a conveying the substrate holder 11 in the first moving direction along the conveyance path, the return path side conveyance portion 33c conveying the substrate holder 11 in the second moving direction, which is a direction opposite to the first moving direction, along the conveyance path, and the turning conveyance portion 30B turning and conveying the substrate holder 11 from the forward path-side conveyance portion 33a to the return path-side conveyance portion 33c in a state where a relationship between upper and lower portions of the substrate holder 11 is maintained, the forward path-side conveyance portion 33a is configured to pass through the first film formation region 4, and the return path-side conveyance portion 33c is configured to pass through the second film formation region 5. Therefore, it is possible to provide a pass-through film formation apparatus 1 capable of efficiently forming films on both surfaces of the substrate 10 and having a small and simple configuration.

In addition, in the present embodiment, the first and second shield portions 15 and 16 shielding the film forming material and having a protrusion shape are provided on the end portion of the downstream side and the end portion of the upstream side in the moving direction of the substrate holder 11, respectively, and the first and second shield portions 15 and 16 are provided such that the substrate holders 11 adjacent to each other overlap each other in a state where they are close to each other at the time of being conveyed. Therefore, it is possible to further reduce the amount of the film formation material attached to the inside of the vacuum chamber 2, and it is possible to certainly prevent contamination of the film formation material in the vacuum chamber 2.

On the other hand, in the present embodiment, the substrate-holder conveyance mechanism 3 has the first and second driving portions 21 and 22 so as to protrude outward from the conveyance driving members 33 disposed on the continuous conveyance driving members 33 hung across the first and second driving wheels 31 and 32 having the circular shape, and when the first driving portion 21 of the first and second driving portions 21 and 22 passes through the first driving wheel 31 of a side introducing and ejecting the plurality of substrate holders 11 along the arc of the first driving wheel 31, the first driving portion 21 is configured to be in contact with the second driven portion 13 of the substrate holder 11 and press and move the second driven portion 13 at a speed higher than conveyance speeds of the forward path-side conveyance portion 33a and the return path-side conveyance portion 33c in the moving direction. Therefore, in a state where the forward path-side conveyance portion 33a and the return path-side conveyance portion 33c are conveyed at a predetermined speed, when the substrate holder 11 passes through the first driving wheel 31 in the case where the substrate holder 11 is introduced from the first driving wheel 31 side, the substrate holder 11 can be accelerated by the first driving portion 21 of the conveyance driving member 33. As a result, the introduced substrate holder 11 can be disposed to automatically approach the preceding substrate holder 11.

In addition, in the state where the forward path-side conveyance portion 33a and the return path-side conveyance portion 33c are conveyed at the predetermined speed, when the substrate holder 11 is ejected from the first driving wheel 31 side, the substrate holder 11 can also be accelerated by the first driving portion 21 of the conveyance driving member 33. As a result, the ejected substrate holder 11 can be automatically spaced apart from the following substrate holder 11 and be smoothly ejected.

In particular, the height H₁ of the first driving portion 21 which is the driving portion for acceleration, with respect to the conveyance driving member 33 is higher than the height H₂ of the second driving portion 22 which is another driving portion with reaped to the conveyance driving member 33 (H₁>H₂).

When the first driving potion 21 is in contact with the second driven portion 13 of the substrate holder 11, the first driving portion 21 is configured to rotationally move while being in contact with the second driven portion 13 of the substrate holder 11 on a concentric circle having a diameter greater than the diameter of the first driving wheel 31. Therefore, with a very simple am figuration, when the substrate holder 11 passes through the first driving wheel 31 in the case where the substrate holder 11 is introduced from the first driving wheel 31 side or when the substrate holder 11 is ejected from the first driving wheel 31 side, the substrate holder 11 can be easily accelerated by the first driving portion 21 of the conveyance driving member 33.

In addition, in the present embodiment, the substrate holder 11 is configured to arrange and hold the plurality of substrates 10 in a direction orthogonal to the moving direction. Therefore, it is possible to reduce a length of the substrate holder and a surplus space depending on the length of the substrate holder as compared with the case where film formation is performed by conveying the substrate holder arranging and holding the plurality of substrates in the moving direction of the substrate as in the conventional technology, and it is thus possible to further save a space of the film formation apparatus.

It should be noted that the embodiments are not limited to the above-discussed embodiment, and can be variously modified.

For example, in the above embodiment, the conveyance driving member of the upper side of the conveyance driving members 33 is defined as the forward path-side conveyance portion 33a which is the first conveyance portion, and the conveyance driving member of the lower side of the conveyance driving members 33 is defined as the return path-side conveyance portion 33c which is the second conveyance portion. However, the present embodiment is not limited thereto, and a relationship between the upper side and the lower side of the conveyance driving members 33 can be inverted.

In addition, the shapes of the first and second driving portions 21 and 22 are not limited to the shapes of the aforementioned embodiment and various shapes can he adopted as long as the first and second driving portions 21 and 22 can surely be in contact with and press and move the first and second driven portions 12 and 13.

Further, the present embodiment can be applied to a case where the substrate 10 before the film is formed is carried together with the substrate holder 11 into the vacuum chamber 2 and the substrate 10A on which the film is formed is carried together with the substrate holder 11 out of the vacuum chamber 2 as well as a case where the substrate 10 before the film is formed is carried into the vacuum chamber 2 and the substrate 10A on which the film is formed is carried out of the vacuum chamber 2 as in the above embodiment.

It should be noted that the forward path-side conveyance portion oi the upper side is defined as the first conveyance portion and the return path-side conveyance portion of the lower side is defined as the second conveyance portion in the above example, but the forward path-side conveyance portion of the upper side may be defined as the second conveyance portion, the return path-side conveyance portion of the lower side may be defined as the first conveyance portion, the film may be formed by the second conveyance portion, and then the film may be formed by the first conveyance portion. In addition, the forward path-side conveyance portion may be disposed on the lower side and the return path-side conveyance portion may be disposed on the upper side.

It should be noted that in one embodiment of the substrate holder, the first driven portion 12 may be referred to as a downstream side driven portion because the first driven portion 12 is positioned at a downstream side of the substrate-holder conveyance mechanism 3. Likewise, the second driven portion 13 may be referred to as an upstream side driven portion because the second driven portion 13 is positioned at an upstream side of the substrate-bolder conveyance mechanism 3.

### REFERENCE SIGNS LIST

1 film formation apparatus
2 vacuum chamber
3 substrate-holder conveyance mechanism
4 first film formation region
4T sputtering source
5 second film formation region
5T sputtering source
6 substrate carry-in and carry-out mechanism
10 substrate
11 substrate holder
11A preceding side substrate holder
11B following side substrate holder
12 first driven portion (driven portion)
13 second driven portion (driven portion)
15 first shield portion (shield portion)
16 second shield portion (shield portion)
21 first driving portion (driving portion, driving portion for acceleration)
22 second driving portion (driving portion)
30A substrate-holder introduction portion
30B turning conveyance portion
30C substrate-holder ejection portion
31 first driving wheel (first rotation driving means)
32 second driving wheel (second rotation driving means)
33 conveyance driving member
33a forward path-side conveyance portion (first conveyance portion)
33b turning portion
33c return path-side conveyance portion (second conveyance portion)

What is claimed is:

1. A film formation apparatus comprising:
a vacuum chamber in which a single vacuum environment is formed;
a first film formation region provided in the vacuum chamber, the first film formation region being configured to form a first film on a substrate held by a substrate holder;
a second film formation region provided below or above the first film formation region in the vacuum chamber, the second film formation region being configured to form a second film on the substrate held by the substrate holder; and
a substrate-holder conveyance mechanism configured to allow the substrate holder to pass through the first film formation region and the second film formation region, the substrate-holder conveyance mechanism including:
a conveyance path formed with a ring shape on a vertical plane;
a driving portion in contact with a driven portion provided on the substrate holder, the driving portion being configured to press the driven portion while maintaining a horizontal state of the substrate holder and move the substrate holder along the conveyance path;
a first conveyance portion disposed from a first end of the first film formation region to a second end of the first film formation region so as to allow the substrate holder to pass through the first film formation region by the driving portion;
a second conveyance portion disposed from a first end of the second film formation region to a second end of the second film formation region so as to allow the substrate holder to pass through the second film formation region by the driving portion;
a turning conveyance portion configured to move the substrate holder from the first conveyance portion to the second conveyance portion while maintaining the horizontal state of the substrate holder; and
a driving portion turning portion configured to move the driving portion from the second conveyance portion to the first conveyance portion.

2. The film formation apparatus according to claim 1, further comprising shield portions having a protrusion shape and provided on an end portion of a downstream side in a moving direction of the substrate holder, and on an end portion of an upstream side in the moving direction of the substrate holder, so as to shield a film forming material.

3. The film formation apparatus according to claim 2, wherein a shield portion of an upstream side in the moving direction of a preceding substrate holder and a shield portion of a downstream side in the moving direction of a following substrate holder of the shield portions among the preceding substrate holder and the following substrate holder moving adjacent to each other are formed having different heights from a bottom surface of each of the respective preceding substrate holder and following substrate holder, such that the shield portion of the upstream side and the shield portion of the downstream side are disposed to overlap each other when the preceding substrate holder and the following substrate holder are moved.

4. The film formation apparatus according to claim I, wherein:
the substrate-holder conveyance mechanism includes a conveyance driving member applied across two driving wheels rotating around rotation axes,
the driving portion includes a first driving portion and a second driving portion each provided in the conveyance driving member,
the driven portion of the substrate holder includes an upstream side driven portion provided on an upstream side in a moving direction of the substrate holder and a downstream side driven portion provided on a downstream side in the moving direction of the substrate holder,
the second driving portion is in contact with the downstream side driven portion, and the driving portion presses the downstream side driven portion to linearly move the substrate holder, and
the first driving portion is disposed behind the second driving portion in the moving direction, the first driving portion being positioned on a side surface of the driving wheel, the driving wheel being positioned on the upstream side in the moving direction of the substrate holder, the substrate holder being linearly moved by the second driving portion, the first driving portion being configured to commence contact with the upstream side driven portion after the second driving portion has contacted the downstream side driven portion, and the first driving portion pressing the upstream side driven portion during rotation so as to move the substrate holder at a speed higher than a moving speed of the second driving portion.

5. The film formation apparatus according to claim 1, wherein the substrate holder is configured such that a plurality of substrates to be film-formed are arranged along a direction orthogonal to a moving direction.
